(19) United States
(12) Patent Application Publication
(10) Pub. No.: US 2007/0238327 A1
(43) Pub. Date: Oct. 11, 2007

(54) Burn-in socket with organizer arranging cable

(75) Inventor: Hsiu-Yuan Hsu, Tu-Cheng (TW)

Correspondence Address: WEI TE CHUNG;FOXCONN INTERNATIONAL, INC., 1650 MEMOREX DRIVE, SANTA CLARA, CA, 95050, US

(73) Assignee: HON HAI PRECISION IND. CO., LTD.

(21) Appl. No.: 11/784,837

(22) Filed: Apr. 10, 2007

(30) Foreign Application Priority Data
Apr. 10, 2006 (TW) 95205946

(51) Int. Cl. H01R 13/60; H05K 1/00

(52) U.S. Cl. 439/70; 439/331; 439/41

(57) ABSTRACT

A burn-in socket assembly comprises a housing assembly with a plurality of contacts arranged therein. Each contact includes a contact engaging portion extends above a supporting surface of the housing assembly and located within a package receiving space. A pusher assembly pivotally assembles to a first side of the housing assembly and includes a pusher. A heat generating and sensor assembly is supported on the pusher, and includes a cable extending away and outward of the pusher. A latch pivotally assembles on the pusher assembly for securely locking the pusher assembly to the housing assembly. Wherein an organizer is arranged on the housing assembly such that the cable is securely arranged and protected therein.

### FIELD OF THE INVENTION

The present invention relates to burn-in socket, and more particularly to a burn-in socket in which organizer is provided such that a flat flexible cable can be securely arranged therein.

### DESCRIPTION OF PRIOR ART

Central Processing Unit (CPU) and other electrical package, generally referred to as Package, are undergone a test simulating its real working environment so as to make sure it functions from all intended ranges.

A so-called Burn-In Socket is introduced, and which includes a floatable housing supported by springs and on which the Package is seated. The Burn-in Socket further includes a Pusher assembly pushing the Package toward the housing such that the Package is electrically contacted with all contacts assembled within the socket.

Before an Active Thermal Control (ATC) Assembly is used, Burn-in Socket along with the Package are set in an oven heated to a working temperature. Then after a certain period of time or cycle, the Package is removed for inspection.

After the ATC is introduced, the followings are achieved. 1) Each socket is directly heated/cooled; 2) each socket/device includes an individual temperature monitoring such that a specific temperature can be maintained/assured by the ATC; and 3) Cooling/Heating of each socket is controlled through an individual fans or heater associated to each socket. Accordingly, temperature uniformity can be controlled within +/−5 degrees Celcius.

However, one of issues associated with the ATC system is the wire harness, i.e. cable used to power the heat generating device, and also signal wire picking up signal from the sensors. Since each time a socket completes its test, the Burn-in socket is opened to remove the Package, and then a new Package is disposed for test. If the wire harness is not well organized, the performance of the ATC will be compromised, and also once the wire harness is damaged, the whole Burn-In socket can be blown out.

Accordingly, there is a need to have the Burn-in Socket provided with an arrangement such that the wire harness well organized, and protected, such that the repeated operation of the Burn-in Socket will not impose any negative effect to the Burn-In Socket.

### SUMMARY OF THE INVENTION

It is therefore the object of the present invention to provide a Burn-in Socket, provided with an organizer such that the wire harness of a heat generating and sensor assembly can be well organized and protected, therefore will not be damaged.

In order to achieve the object set forth, an Burn-in Socket made in accordance with the present invention comprises a housing assembly with a plurality of contacts arranged therein. Each contact includes a contact engaging portion extends above a supporting surface of the housing assembly and located within a package receiving space. A pusher assembly pivotally assembles to a first side of the housing assembly and includes a pusher. A heat generating and sensor assembly is supported on the pusher, and includes a cable extending away and outward of the pusher. A latch pivotally assembles on the pusher assembly for securely locking the pusher assembly to the housing assembly. Wherein an organizer is arranged on the housing assembly such that the cable is securely arranged and protected therein.

According to one aspect of the present invention, the organizer includes first and second arms extending toward from each other from an outer wall of the first housing and jointly defining a slot.

According to another aspect of the present invention, wherein the wire harness, which is the FPC, and the flat flexible cable is securely arranged within the slot defined by the first and second arms.

### BRIEF DESCRIPTION OF THE DRAWINGS

Other objects, advantages and novel features of the present invention will become more apparent from the following detailed description when taken in conjunction with the accompanying drawings, in which:

FIG. 1 is an exploded view of a Burn-in Socket made in accordance with the present invention, FIG. 1A is a partial cross sectional view of a housing assembly;

FIG. 2 is an assembled view in which a latch thereof is unlocked;

FIG. 3 is similar to FIG. 2, with the latch locked;

FIG. 4 is an assembled view showing a heat generating and sensor assembly assembled in the Burn-in Socket;

FIG. 5 is a perspective view of a Burn-in Socket, in which a pusher is tilted to an opened position; and

FIG. 6 is a perspective view of a heat generating and sensor assembly.

### DETAILED DESCRIPTION OF PREFERRED EMBODIMENT

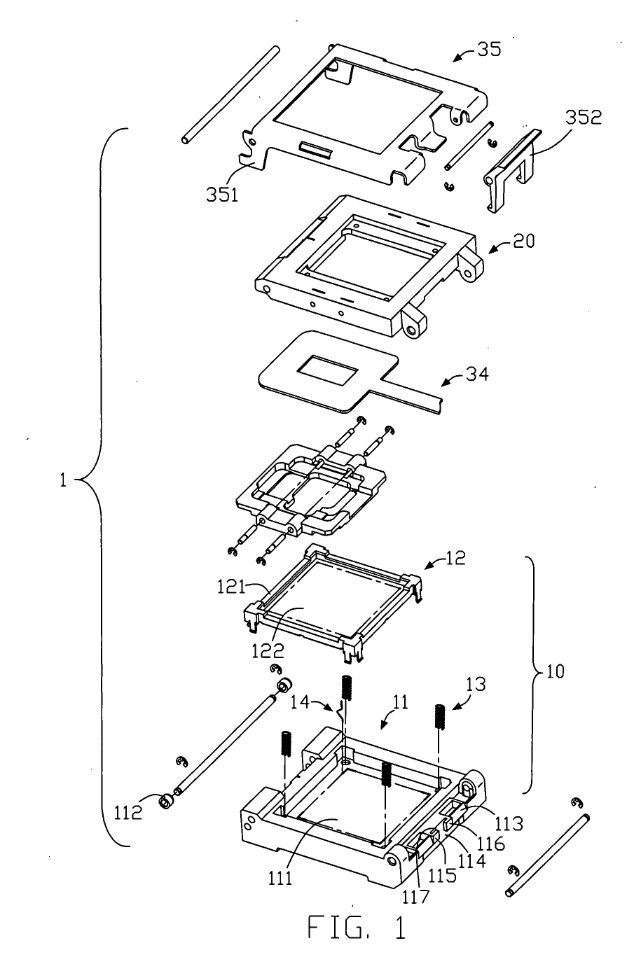

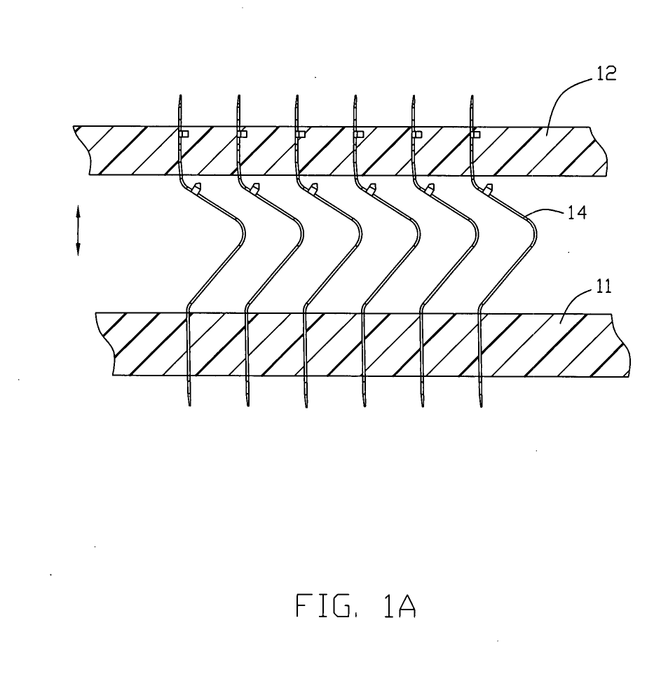

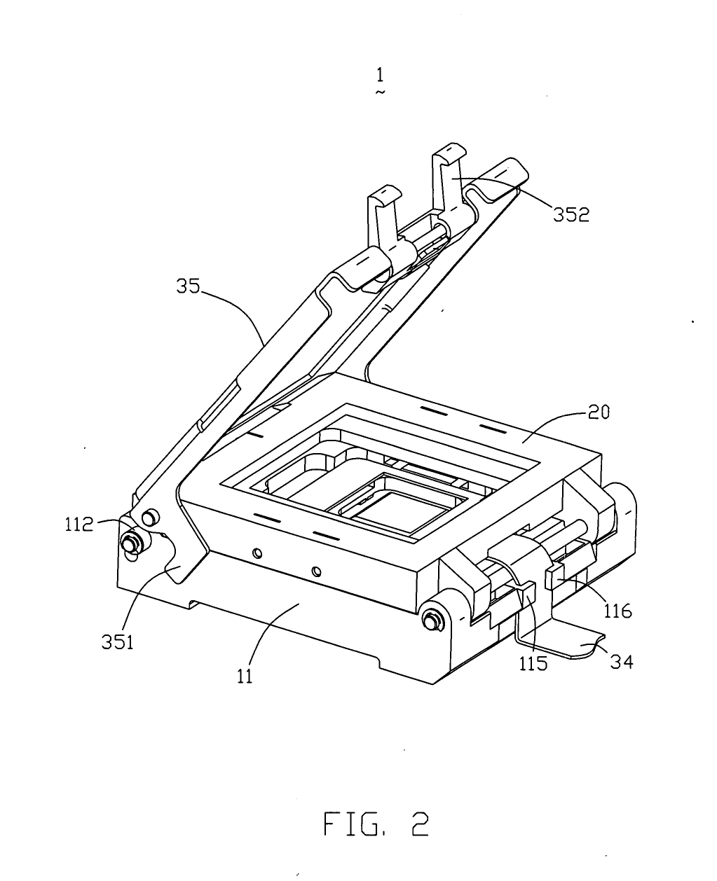

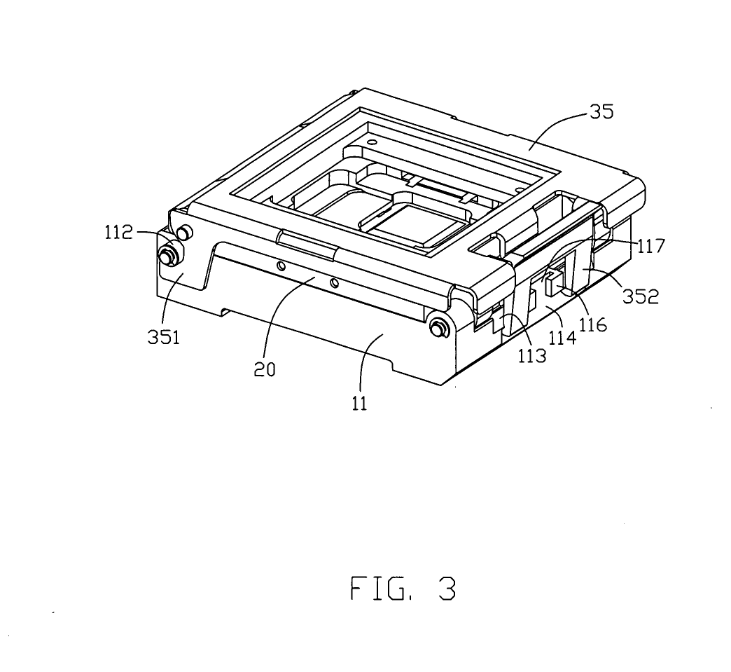

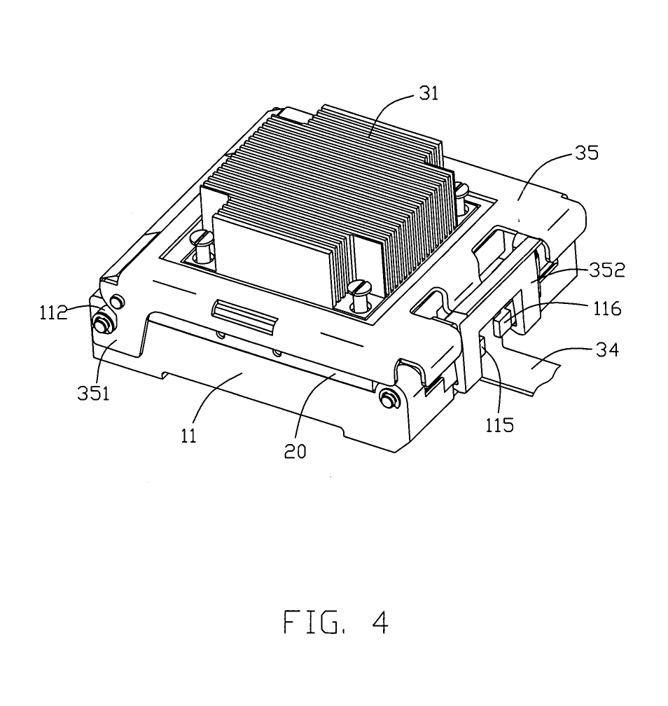

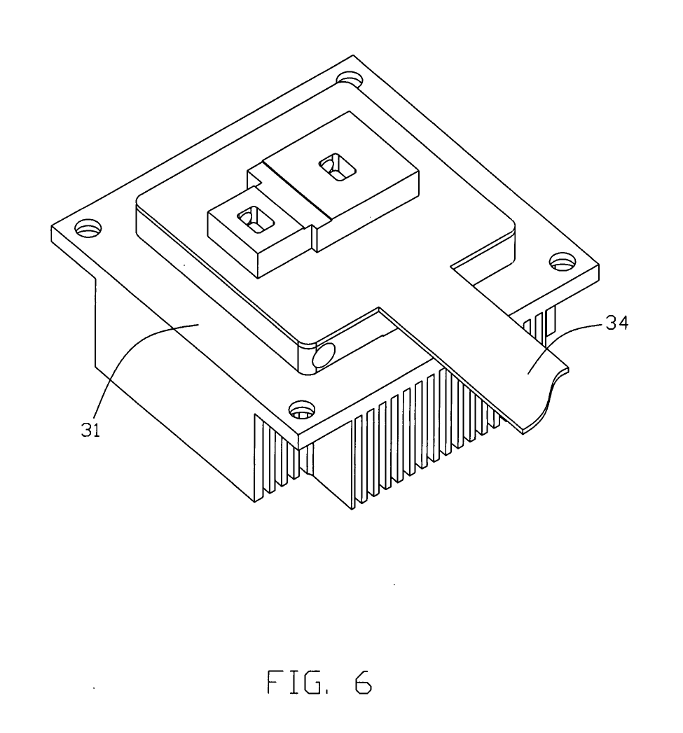

Referring to FIGS. 1 to 6, particularly to FIG. 1. A burn-in socket 1 made in accordance with the present invention comprises a housing assembly 10 including a first housing 11, and second housing 12 floatably attached to the first housing 11. The second housing 12 is floatably supported on the first housing 11 by means of four coil spring 13 or other equivalent. The first housing 11 defines a space 111 to receive the second housing 12. Both of the first housing 11 and second housing 12 are provided with passageways in which each is assembled with a contact 14.

The second housing 12 defines a mating interface or supporting surface 120, in which a contact engaging portion 141 of the contact 14 extends beyond the mating interface 120 so as to electrically engage with an electrical package. The contact 14 further includes a compliant portion 142 which will deform to accommodate the downward movement of the second housing 12 with respect to the first housing 11. The second housing 12 has peripheral wall 121 which defines a package receiving space 122 jointly with the mating interface 120, and properly receives the package therein.

A pusher assembly 20 pivotally assembled to a first side 110 of the first housing 11, and includes a pusher 21. The pusher assembly 20 includes an opening 201 in which the pusher 21 is snugly assembled therein. The pusher 21 defines also an opening 210 which will in align with the package seated on the second housing 12.

A heat generating and sensor assembly 30 is securely supported on the pusher assembly 20. The assembly 30 includes a heatsink 31 in which at least a heat generating device, and a sensor are mounted (not shown in Figures). The assembly 30 also includes a cable 34 providing power to the heat generating device 32, and picking up signal from the sensor 33. The cable 34, according to a preferred embodiment of the present invention, is a FPC, flat flexible cable. Of course, other type of cable are also acceptable, as long as it makes the assembly 30 works according to its intended purpose.

A latch 35 is pivotally assembled on the assembly 30 for securely locking the assembly 30 to the first housing 11. The latch includes a hook 351 which can be locked to an anchor 112 on the first housing 11. The latch 35 further includes a tab 352 interlocked to a mount 113 of the first housing 11.

In order to well keep the FPC 34 organized, an organizer 114 is arranged on the first housing 11 adjacent to the mount 113 of the first housing 11. The organizer 114 is integrally formed with the first housing 11, and includes first and second arms 115, 116 extending toward from each other from an outer wall of the first housing 11 and jointly defining a slot 117. The FPC 34 can inserted and well organized within the slot 117 defined by the first and second arms 115, and 116.

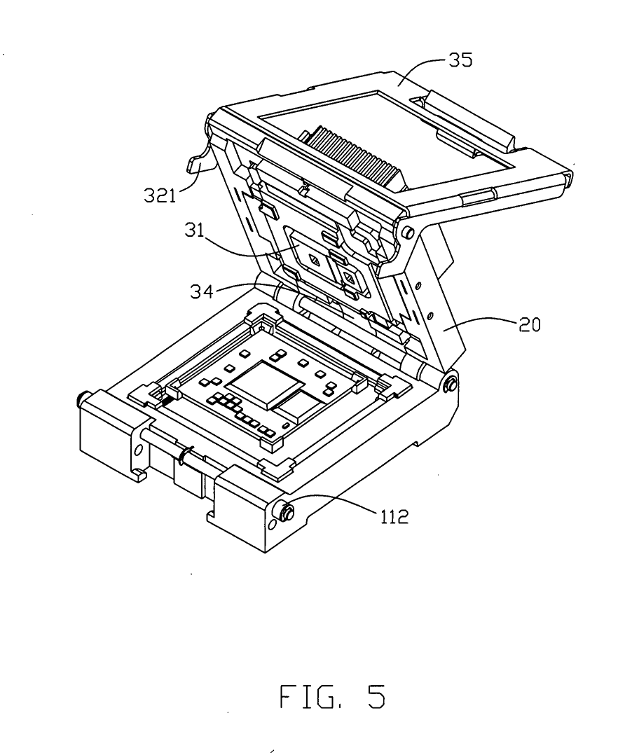

In operation, the latch 35 is firstly unhooked from the anchor 112 such that the assembly 30 can be tilted to an opened position, such as shown in FIG. 5. Then, the package to be tested can be seated onto the mating interface 120 which is accessible from this tilted position. After the package is well seated, the assembly 30 is closed, and the latch 35 is locked again to the anchor 112, and the tab 352 is hooked to the mount 113. And then the testing cycle can be commenced.

It can be well noticed that since the cable 34 is well seated and protected within the organizer 114, the cable 34 will then be well protected and secured.

Although the present invention has been described with reference to particular embodiments, it is not to be construed as being limited thereto. Various alterations and modifications can be made to the embodiments without in any way departing from the scope or spirit of the present invention as defined in the appended claims.

1. A burn-in socket assembly, comprising:
a housing assembly including a first housing, and second housing floatably attached to the first housing, the second housing defining a supporting surface on which a package receiving space is defined, a plurality of contacts arranged between the first and second housing, and each contact including a contact engaging portion extending above the supporting surface of the second housing and located within the receiving space;
a pusher assembly pivotally assembled to a first side of the first housing, and including a pusher;
a heat generating and sensor assembly supported on the pusher, and including a cable extending away and outward of the pusher;
a latch pivotally assembled on the pusher assembly for securely locking the pusher assembly to the housing assembly; and
wherein an organizer is arranged on the housing assembly such that the cable is securely arranged therein.

2. A burn-in socket assembly as recited in claim 1, wherein the organizer is arranged at the first housing.

3. A burn-in socket assembly as recited in claim 2, wherein the organizer is integrally formed with the first housing.

4. A burn-in socket assembly as recited in claim 2, wherein the organizer includes first and second arms extending toward from each other from an outer wall of the first housing and jointly defining a slot.

5. A burn-in socket assembly as recited in claim 1, wherein the cable is a flat flexible cable (FPC).

6. A burn-in socket assembly as recited in claim 5, wherein the flat flexible cable is securely arranged within the slot defined by the first and second arms.

7. A socket assembly, comprising:
a housing assembly having contacts therein surrounded by side walls;
a pusher assembly pivotally assembled to a first side of the first housing, and including a pusher;
a heat generating and sensor assembly supported on the pusher, and including a cable extending away and outward of the pusher;
a latch pivotally assembled on the pusher assembly for securely locking the pusher assembly to the housing assembly; and
one of the side walls defines a cable organizer to snugly receive the cable.
